(19) United States
(12) Patent Application Publication
(10) Pub. No.: US 2019/0150321 A1
(43) Pub. Date: May 16, 2019

(54) DEVICE FOR COOLING ELECTRONIC COMPONENTS

(71) Applicant: FUJITSU LIMITED, Kawasaki-shi (JP)

(72) Inventors: Keita Hirai, Kawasaki (JP); Tsuyoshi So, Kawasaki (JP); Naofumi Kosugi, Yokohama (JP)

(73) Assignee: FUJITSU LIMITED, Kawasaki-shi (JP)

(21) Appl. No.: 16/180,070

(22) Filed: Nov. 5, 2018

(30) Foreign Application Priority Data
Nov. 16, 2017 (JP) 2017-220988

(51) Int. Cl. H05K 7/20; F24F 3/14; H05K 5/02

(52) U.S. Cl. CPC H05K 7/20736; F24F 3/14; F24F 2003/144; H05K 5/0213; H05K 7/20809

(57) ABSTRACT

A device for cooling electronic components includes: a main body including the electronic components; an air blower configured to introduce air into the main body; a heat exchanger configured to cool air introduced into the main body; an evaporator with which air discharged from the main body comes into contact. The device further includes a pump configured to draw up water generated by dew condensation in the heat exchanger and to supply the water to a top portion of the evaporator.

### CROSS-REFERENCE TO RELATED APPLICATION

This application is based upon and claims the benefit of priority of the prior Japanese Patent Application No. 2017-220988, filed on Nov. 16, 2017, the entire contents of which are incorporated herein by reference.

### FIELD

The embodiments discussed herein are related to a device for cooling electronic components, such as an information processing apparatus.

### BACKGROUND

There is known an information processing apparatus that includes a heat exchanger that cools air introduced into an information processing apparatus main body, an evaporator through which air discharged from the information processing apparatus main body passes, and a receiving pan that receives water generated by dew condensation in the heat exchanger, wherein water in the receiving pan is supplied via a pipe to a water storage pan at the bottom of the evaporator. Related techniques are disclosed in, for example, Japanese Laid-open Patent Publication No. 2017-92109.

However, with the related technique as described above, it is difficult, in some cases, to efficiently evaporate water generated by dew condensation by using the evaporator. For example, in the case where the evaporator is a member that pumps water in the water storage pan by capillary action, there is a limit to how high water may be pumped and it is difficult, in some cases, to evaporate water by making use of the full height of the evaporator.

Accordingly, the embodiments discussed herein, for example, provide techniques to enable water generated by dew condensation to be efficiently evaporated by using an evaporator.

### SUMMARY

According to an aspect of the embodiments, a device for cooling electronic components includes: a main body including the electronic components; an air blower configured to introduce air into the main body; a heat exchanger configured to cool air introduced into the main body; an evaporator with which air discharged from the main body comes into contact, and a pump configured to draw up water generated by dew condensation in the heat exchanger and to supply the water to a top portion of the evaporator.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic diagram illustrating a device for cooling electronic components according to a first embodiment;

FIG. 2 is a schematic diagram illustrating a structure of a heat exchanger;

FIG. 3 is a schematic diagram illustrating a structure of an evaporator;

FIG. 4 is a dew-point table used when determining a dew point (° C.) from the temperature of air (air temperature: ° C.) and relative humidity (% RH);

FIG. 5A is a diagram illustrating an example of a change in temperature of air inside and outside an information processing apparatus;

FIG. 5B is a diagram illustrating positions of a to d in FIG. 5A;

FIG. 6A is a diagram illustrating a configuration of a pump control system of an information processing apparatus according to a first embodiment;

FIG. 6B is a schematic flowchart illustrating an example of a process of a pump control system;

FIG. 7 is a schematic diagram illustrating a device for cooling electronic components according to a second embodiment;

FIG. 8 is a schematic diagram illustrating a device for cooling electronic components according to a third embodiment;

FIG. 9 is a schematic diagram illustrating a device for cooling electronic components according to a fourth embodiment;

FIG. 10A is a schematic diagram illustrating a side view of a device for cooling electronic components according to a fifth embodiment;

FIG. 10B is a schematic diagram illustrating a top view of a device for cooling electronic components according to a fifth embodiment;

FIG. 11 is a two-view drawing illustrating an evaporator by way of example;

FIG. 12 is an illustrative diagram of functions of an evaporator by way of example;

FIG. 13 is a two-view drawing illustrating an evaporator by way of another example; and

FIG. 14 is an illustrative diagram of functions of an evaporator by way of another example.

### DESCRIPTION OF EMBODIMENTS

Hereinafter, embodiments will be described in detail with reference to the accompanying drawings.

### First Embodiment

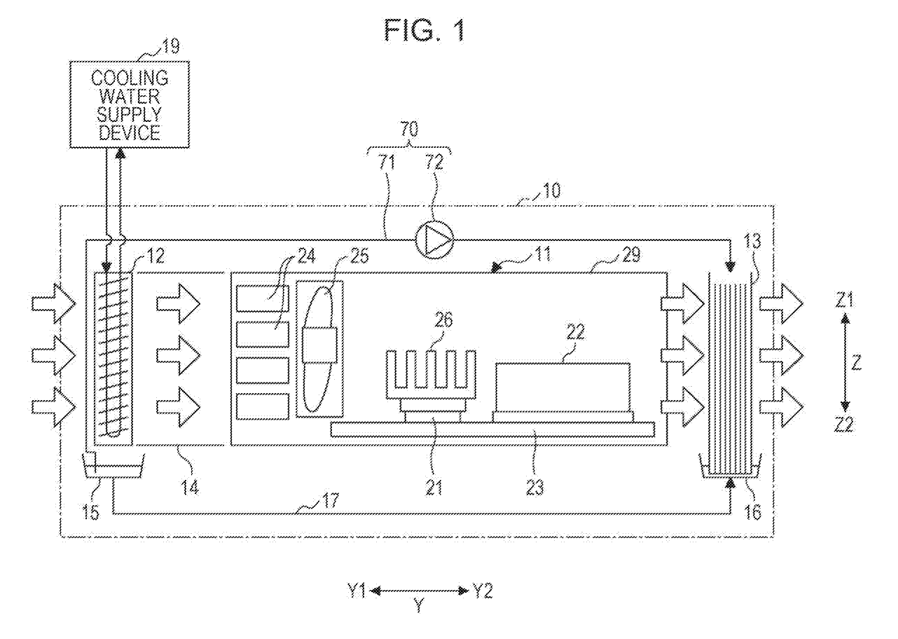

FIG. 1 is a schematic diagram illustrating a device for cooling electronic components, such as an information processing apparatus, according to a first embodiment. In the first embodiment, the case where an information processing apparatus main body is a server is described. The arrows in FIG. 1 indicate the direction of air flow. In FIG. 1, the Y-direction and the Z-direction are illustrated. The Z-direction corresponds to the direction of gravity and the side of Z1 is the upper side. For the Y-direction, the side of Y1 corresponds to the upstream side (upstream side in the direction of air flow), that is, an air intake side.

The information processing apparatus 10 according to the first embodiment includes an information processing apparatus main body 11, a heat exchanger 12, and an evaporator 13. The heat exchanger 12 is disposed on one side (air intake surface) of the information processing apparatus main body 11, and the evaporator 13 is disposed on the opposite side (air discharge surface side) of the heat exchanger 12 across the information processing apparatus main body 11. The air intake surface and the air discharge surface are normal to the Y-direction. In areas where an air intake surface and an air discharge surface are formed, vent holes, openings, or the like (not illustrated) may be formed. A duct 14 is provided between the heat exchanger 12 and the information processing apparatus main body 11 such that air that has passed through the heat exchanger 12 enters inside the information processing apparatus main body 11.

A receiving pan 15 is disposed below the heat exchanger 12. As described below, cooling water (refrigerant) at a low temperature is supplied from a cooling water supply device 19 to the heat exchanger 12, and therefore dew condensation sometimes occurs inside the heat exchanger 12. Water generated by dew condensation (hereinafter also referred to as condensation water) in the heat exchanger 12 falls by gravity into the receiving pan 15.

In contrast, a water storage pan 16 is disposed below the evaporator 13. The receiving pan 15 and the water storage pan 16 communicate with each other by a flow channel 17 (an example of a second flow channel). The flow channel 17, for example, may be an air release flow channel or may be formed of a set of capillaries. The condensation water in the receiving pan 15 moves through the flow channel 17 to the water storage pan 16. As the flow channel 17, a pipe made of, for example, resin may be used.

The information processing apparatus main body 11 further includes a supply section 70. The supply section 70 supplies water generated by dew condensation (condensation water) in the heat exchanger 12 to the top of the evaporator 13.

In the first embodiment, the supply section 70 includes, by way of example, a flow channel 71 (an example of a first flow channel) and a pump 72.

The flow channel 71 extends from the receiving pan 15 to the top of the evaporator 13. As the flow channel 71, a pipe made of, for example, resin may be used. The detailed path (the path from the receiving pan 15 to the top of the evaporator 13) of the flow channel 71 is an arbitrary path and may be in such a manner, for example, as to pass inside the information processing apparatus main body 11 or pass outside the information processing apparatus main body 11. In contrast to the flow channel 17, the flow channel 71 may not be connected to the bottom surface (lowest portion) of the receiving pan 15, and, for example, as schematically illustrated in FIG. 1, the flow channel 71 is disposed inside the receiving pan 15 in such an orientation that the lower side of the flow channel 71 is open. However, the flow channel 71 may be connected to the bottom surface of the receiving pan 15 in such an orientation that the upper side of the flow channel 71 is open.

The pump 72 draws up condensation water from the receiving pan 15 and supplies the condensation water to the top of the evaporator 13. The pump 72 may be, for example, electrically operated. The pump 72 may be of a fixed capacity type or may be of a variable capacity type.

In a modification, the flow channel 17 and the flow channel 71 may take the form in which the flow channel 17 and the flow channel 71 branch off from a common flow channel from the receiving pan 15. In this case, the common flow channel is connected to the receiving pan 15. The common flow channel may be, for example, an air release flow channel. In this case, the pump 72 may be provided in the common flow channel or may be provided in the flow channel 71 after branching off from the common flow channel.

The information processing apparatus main body 11 includes a circuit board 23, hard disk drives (HDDs) 24, an air blower (cooling fan) 25, and a housing 29 that houses these components. On the circuit board 23, a central processing unit (CPU) 21, a memory 22, a heat sink 26, and other electronic components are mounted.

All the HDDs 24, the CPU 21, and the memory 22 are examples of heat-generating components. In the first embodiment, the HDDs 24 are arranged between the air intake surface of the housing 29 and the air blower 25.

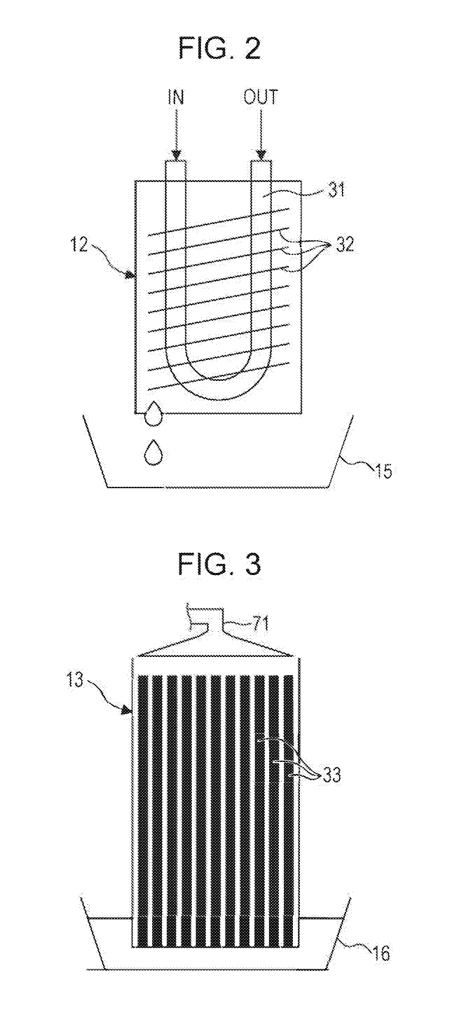

FIG. 2 is a schematic diagram illustrating a structure of the heat exchanger 12. As illustrated in FIG. 2, the heat exchanger 12 includes a cold water pipe 31 (an example of a conduit) and multiple fins 32 arranged along the longitudinal direction of the cold water pipe 31. Cooling water (refrigerant) is supplied to the cool water pipe 31 from the cooling water supply device 19 (refer to FIG. 1) placed, for example, outdoors. The type of the cooling water supply device 19 is not limited. For example, here, an air-cooled chiller is used as the cooling water supply device 19. The temperature of cooling water supplied to the cool water pipe 31 may be appropriately set. For example, here, the temperature of cooling water supplied to the cool water pipe 31 is about 10° C. to 15° C.

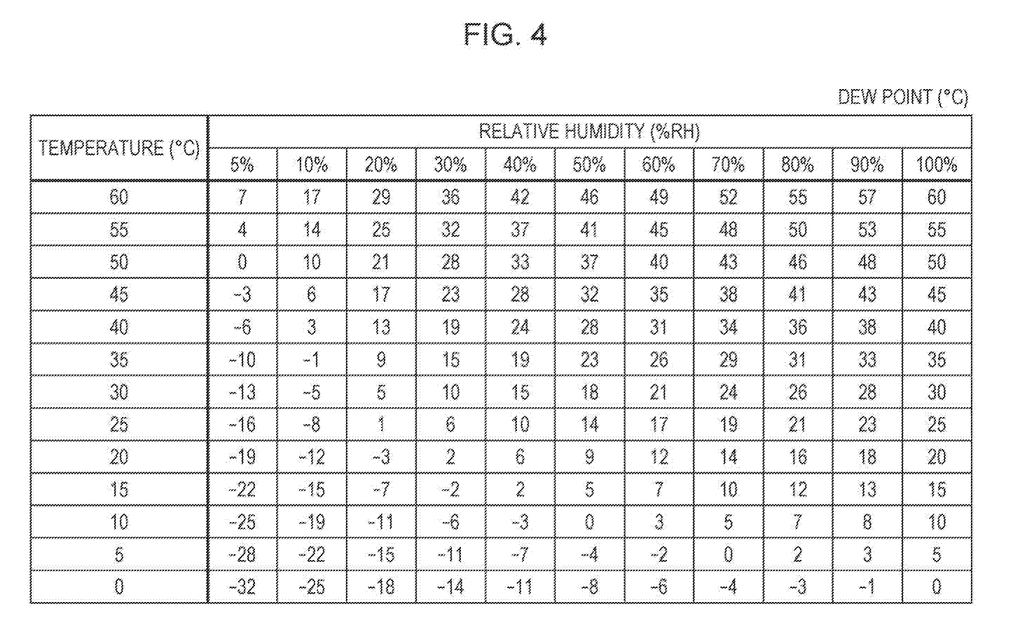

FIG. 3 is a schematic diagram illustrating a structure of the evaporator 13.

The evaporator 13 has a height approximately the same as the height of the air discharge surface of the information processing apparatus main body 11. The evaporator 13 also has a width approximately the same as the width (the length in the vertical direction of the plane of FIG. 1) of the air discharge surface of the information processing apparatus main body 11. For example, the evaporator 13 is provided in such a manner as to face the substantial entirety of the air discharge surface of the information processing apparatus main body 11. This enables transpiration of condensation water by making maximum use of air discharge. In a modification, a plurality of evaporators 13 may be provided separately in the width direction thereof for the air discharge surface of the information processing apparatus main body 11.

The evaporator 13 includes multiple capillaries 33 as illustrated in FIG. 3. The capillaries 33 takes the shape of a tube having an inside diameter less than 1 mm. The condensation water in the water storage pan 16 rises up in the capillaries 33 by capillary action. Multiple fine pores are provided in the circumferential surface of each capillary 33. The flow channel 71 is connected to the top of the evaporator 13 as illustrated in FIG. 3. Condensation water supplied via the flow channel 71 to the top of the evaporator 13 descends inside the capillaries 33 by gravity. When air comes into contact with the evaporator 13 containing water relevant to condensation water, evaporation of the condensation water from the capillaries 33 is promoted.

Condensation water from the flow channel 71 may be simply dropped or may be, for example, sprayed in a shower-like manner, in a mist-like manner, or the like onto the top of the evaporator 13. In this regard, condensation water from the flow channel 71 is desirably dropped or, for example, sprayed over the entire top of the evaporator 13. In this case, by efficiently making use of the entire evaporator 13, evaporation of condensation water from the capillaries 33 may be promoted.

In the first embodiment, the capillaries 33 are used in the evaporator 13 as described above. However, instead of the capillaries 33, another member (such as a rod-shaped member with a porous medium or a fiber bundle) capable of pumping up water by capillary action may be used. Description of a further desirable configuration of the evaporator 13 will be given below.

Operations of the information processing apparatus 10 according to the first embodiment will now be described.

Referring again to FIG. 1, when the air blower 25 operates, air (outside air) is introduced via the heat exchanger 12 into the information processing apparatus 10. For example, here, outside air having a temperature of 50° C. and a humidity (relative humidity, the same applies hereinafter) of 60% RH is introduced into the information processing apparatus 10.

Cooling water (refrigerant) is supplied from the cooling water supply device 19 to the heat exchanger 12. For example, here, when outside air passes through the heat exchanger 12, temperature drops to 25° C.

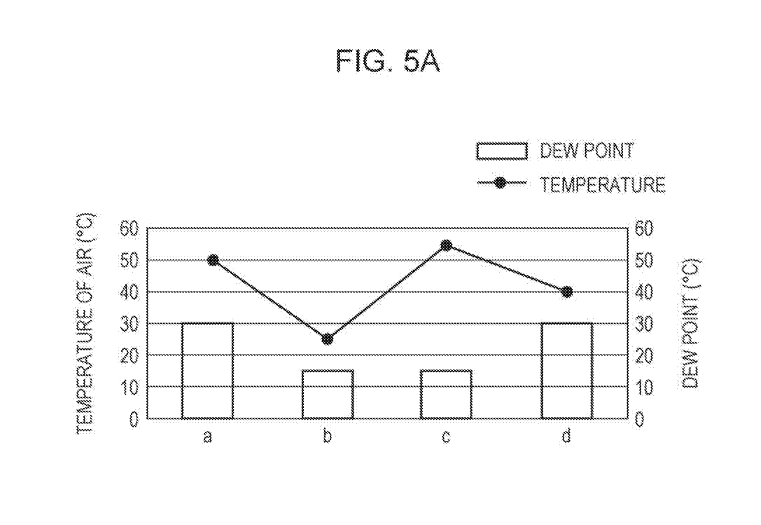

FIG. 4 is a dew point table that is used when a dew point (° C.) is determined from the temperature of air (air temperature: ° C.) and a relative humidity (% RH).

As illustrated in FIG. 4, at a temperature of 50° C. and a relative humidity of 60% RH, the dew point is 40° C. Therefore, if the air (outside air) drops to 25° C., water in the air condenses in the heat exchanger 12, such that water droplets adhere to the surfaces of the fins 32.

The fins 32 are inclined as illustrated in FIG. 2, and therefore water droplets that have grown larger to some extent on the surfaces of the fins 32 slip off the fins 32 to fall into the receiving pan 15. The water (that is, condensation water) that has fallen into the receiving pan 15 moves through the flow channel 17 to the water storage pan 16. During operation of the pump 72, condensation water is supplied through the flow channel 71 to the top of the evaporator 13. In a modification, instead of or in addition to the water storage pan 16, a tank for temporarily storing condensation water may be used. If a tank is used, the flow channel 71 may be connected to the tank, in which case the pump 72 draws up condensation water in the tank and supplies the condensation water to the top of the evaporator 13.

Air that has passed through the heat exchanger 12, as indicated by arrows in FIG. 1, passes inside the duct 14 and enters inside the information processing apparatus main body 11. The air cools the HDDs 24 and further passes through the air blower 25 to cool the CPU 21 connected to the heat sink 26, the memory 22, and the like. At this point, because the temperature of air rises by cooling the HDDs 24, the CPU 21, the memory 22, and the like, the humidity of the air decreases. Thus, dew condensation does not occur inside the information processing apparatus main body 11.

The air whose temperature has risen by cooling the HDDs 24, the CPU 21, and the like passes from the air discharge surface of the information processing apparatus main body 11 through the evaporator 13 and is discharged to the outside.

Air entering the evaporator 13 has a high temperature and a low humidity, and therefore when the air comes into contact with the evaporator 13, the water in the air evaporates from the capillaries 33. As water evaporates, the evaporation heat is removed from the surroundings. Thus, when air comes into contact with the evaporator 13, the temperature of the air decreases and the humidity of the air rises.

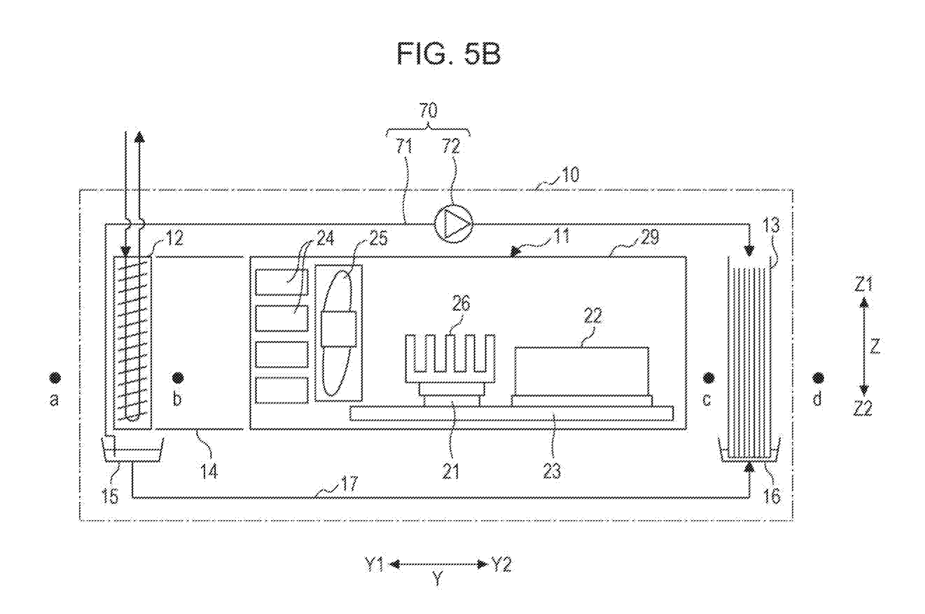

FIG. 5A is a diagram illustrating an example of a change in temperature of air outside and inside the information processing apparatus 10, and FIG. 5B is a diagram illustrating the positions of a to d in FIG. 5A.

As illustrated in FIG. 5A and FIG. 5B, the temperature of air (the temperature at the position a) before entering the information processing apparatus 10 is 50° C. and the dew point at this point is 30° C. When air passes through the heat exchanger 12, the temperature of the air decreases and water in the air is removed because of generation of dew condensation, and thus the temperature of air entering the information processing apparatus main body 11 (the temperature at the position b) is 25° C. and the dew point drops to 15° C.

By cooling the HDDs 24, the CPU 21, the memory 22, and the like, the temperature of air rises. Therefore, the temperature of air (the temperature at the position c) discharged from the information processing apparatus main body 11 is about 55° C., while the dew point is 15° C. because the water content of air remain unchanged.

When air comes into contact with the evaporator 13, the water in the air evaporates, and thus the temperature of the air decreases and the dew point rises. In the example illustrated in FIG. 5A, the temperature of air on an alternating-current side of the evaporator 13 (the temperature at the position d) is 40° C. and the dew point is 30° C.

Electronic components, such as a CPU, used for a server generate a large amount of heat in association with operations of the server. The temperatures of the electronic components exceeding a permissible upper limit of temperature become a cause of a trouble such as failure, malfunction, or a decrease in processing capability. Therefore, in ordinary data centers, air cooled by an air conditioning machine (packaged air conditioner) or the like is supplied to the inside of a server, so that the temperatures of electronic components in the server do not exceed the permissible upper limit of temperature.

In recent years, it has been desired that data centers be placed, for example, in tropical climate countries such as Thailand. However, such countries are hot and humid, causing the cost of temperature control and humidity control to be enormous.

In the first embodiment, the temperature of air introduced into the information processing apparatus main body 11 may be made less than or equal to temperature of the installation environment. As a result, the information processing apparatus 10 according to the first embodiment may be used in hot and humid environments, such as in tropical climate countries.

For example, even in a usage environment in which the room temperature is 50° C. and the dew point is 40° C. (the humidity being about 60% RH), the temperature of air introduced into the information processing apparatus main body 11 may be decreased to about 25° C. and the dew point may be decreased to about 15° C. (the humidity being about 50% RH). This greatly expands regions where information processing facilities such as data centers are able to be placed.

In the first embodiment, since air at a low temperature is introduced into the information processing apparatus main body 11, the load on the air blower 25 is reduced. As a result, the power consumption of the air blower 25 is reduced and noise caused by the air blower 25 is also reduced.

In the case where an information processing apparatus facility is placed in an environment in which the room temperature is 35° C., with the information processing apparatus 10 according to the first embodiment, the power consumption of an air blower may be decreased to about one half of the power consumption with an existing information processing apparatus and the noise may be decreased by 5 dB or more.

Furthermore, in the first embodiment, problems with the temperature and humidity of air introduced into the information processing apparatus main body 11 are solved, and therefore this technique is applicable to outside-air introduction type data centers. In such a case, an indoor air-conditioning machine may become unnecessary, greatly contributing to a reduction in power consumption of a data center.

In the first embodiment, the air blower 25 is inside the information processing apparatus main body 11. However, the air blower 25 may be outside the information processing apparatus main body 11.

In the foregoing description, the humidity of air introduced into the information processing apparatus 10 is high and dew condensation occurs in the heat exchanger 12. If the humidity of air introduced into the information processing apparatus 10 is low, dew condensation does not occur in the heat exchanger 12. However, in such a case, the temperature of air that has passed through the heat exchanger 12 is lower than the temperature of the installation environment, and therefore failure and malfunction of the information processing apparatus 10 may be reduced and effects, such as a reduction in noise and a reduction in power consumption caused by the air blower 25, may be obtained.

According to the first embodiment, the supply section 70 is included, which enables condensation water to be efficiently evaporated by using the evaporator 13. For example, according to the first embodiment, condensation water may be supplied to the top of the evaporator 13. The condensation water supplied to the top of the evaporator 13 is able to move below in the evaporator 13 by a gravitational effect. On this occasion, condensation water is evaporated by air that comes into contact with the evaporator 13, thus effectively achieving transpiration of the condensation water.

In the first embodiment, the amount of condensation water that is able to be supplied (transported) to the top of the evaporator 13 via the flow channel 71 is easily adjustable, for example, by controlling the pump 72. Accordingly, in the first embodiment, the condensation-water transportation capability with the pump 72 does not obstruct transpiration of condensation water. Thus, transpiration of condensation water may be effectively achieved. For example, when condensation water increases in proportion to the airflow volume, the condensation water may be supplied to the top of the evaporator 13 via the flow channel 71 in such a manner as to supplement a condensation-water suction capability by capillary forces. As a result, even when condensation water increases in proportion to the airflow volume, all the condensation water may be returned into the discharged air.

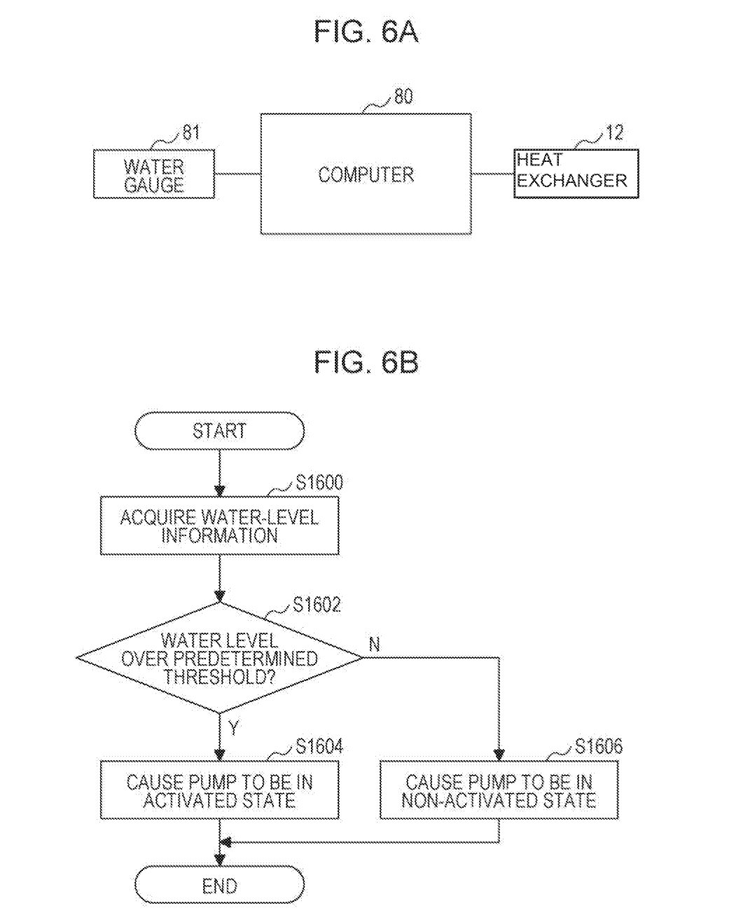

Referring now to FIG. 6A and FIG. 6B, a control system relevant to the pump 72 of the information processing apparatus 10 according to the first embodiment will be described.

FIG. 6A is a configuration diagram of a control system relevant to the pump 72 of the information processing apparatus 10 according to the first embodiment, and FIG. 6B is a schematic flowchart illustrating an example of a process of the control system relevant to the pump 72.

The control system relevant to the pump 72 of the information processing apparatus 10 includes a computer 80 (an example of a control unit). The computer 80 is, for example, a microcomputer or the like. A water gauge 81 and the heat exchanger 12 are connected to the computer 80. The water gauge 81 detects the level of water (the water level of condensation water) in the receiving pan 15. The water gauge 81 may take the shape, for example, of a float.

The computer 80 increases the amount of water (for example, the amount of water per unit time) drawn up by the pump 72 when the amount of condensation water in the receiving pan 15 is greater than a predetermined amount, as compared with the case when the amount of this condensation water is not greater than the predetermined amount. For example, when the amount of condensation water in the receiving pan 15 is greater than the predetermined amount, the computer 80 activates the pump 72, and when this amount is not greater than the predetermined amount, the computer 80 does not activate the pump 72 (that is, causing the drawn-up water amount to be zero). The predetermined amount is an arbitrary amount and may correspond, for example, to the water amount when relatively much condensation water is generated. In the first embodiment, by way of example, the predetermined amount corresponds to the water amount when the water level in the receiving pan 15 is a predetermined threshold. The predetermined threshold is an arbitrary value and may correspond, for example, to the water level when relatively much condensation water is generated.

The computer 80, for example, executes a process as illustrated in FIG. 6B for every predetermined period.

In step S1600, the computer 80 acquires water-level information from the water gauge 81.

In step S1602, the computer 80 determines, based on the water-level information acquired in step S1600, whether the water level in the receiving pan 15 is over the predetermined threshold. If the determination result is “YES”, the process proceeds to step S1604, and if otherwise, the process proceeds to step S1606.

In step S1604, the computer 80 causes the pump 72 to proceed to or to be maintained in the activated state.

In step S1606, the computer 80 causes the pump 72 to proceed to or to be maintained in the non-activated state.

According to the process illustrated in FIG. 6B, the pump 72 may be activated depending on the water-level information from the water gauge 81. This enables condensation water to be efficiently evaporated by using the evaporator 13 while reducing the power consumption of the pump 72 to the minimum.

Although, with reference to FIG. 6B, the pump 72 is controlled between the activated state and the non-activated state, the embodiments are not limited to this. For example, in the case where the pump 72 is a variable capacity type, the capacity of the pump 72 may be variable such that as the water level in the receiving pan 15 rises, the capacity increases. Even in such a case, if the water level of the receiving pan 15 is lower than the predetermined water level, the pump 72 may be in the non-activated state.

### Second Embodiment

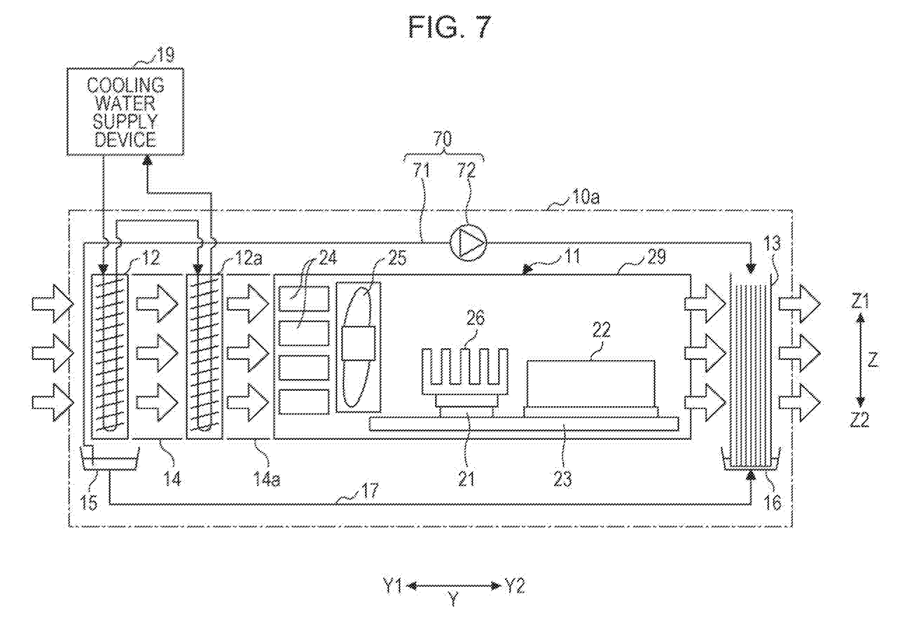

FIG. 7 is a schematic diagram illustrating an information processing apparatus according to a second embodiment. In FIG. 7, the same objects as in FIGS. 1-3 are denoted by the same reference numerals, and a detailed description thereof is omitted.

In an information processing apparatus 10a according to the second embodiment, a second heat exchanger 12a is disposed between the first heat exchanger 12 and the information processing apparatus main body 11. The duct 14 is disposed between the first heat exchanger 12 and the second heat exchanger 12a, and a duct 14a is disposed between the second heat exchanger 12a and the air intake surface of the information processing apparatus main body 11.

As illustrated in FIG. 7, cooling water supplied from the cooling water supply device 19 passes inside the first heat exchanger 12, then passes inside the second heat exchanger 12a, and returns to the cooling water supply device 19.

Hereinafter, operations of the information processing apparatus 10a according to the second embodiment will be described.

When the air blower 25 operates, air is introduced via the first heat exchanger 12 into the information processing apparatus 10a. For example, here, outside air at a temperature of 50° C. and a humidity of 60% RH is introduced into the information processing apparatus 10a.

When passing through the first heat exchanger 12, air is cooled by cooling water passing inside the first heat exchanger 12 to cause dew condensation, such that water droplets adhere to the surfaces of the fins 32 in the first heat exchanger 12. The water droplets adhering to the fins 32 grow larger to some extent and then fall onto the receiving pan 15. The condensation water that has fallen on the receiving pan 15 moves through the flow channel 17 to the water storage pan 16. As in the first embodiment described above, during operation of the pump 72, condensation water is supplied through the flow channel 71 to the top of the evaporator 13.

Air that has passed through the first heat exchanger 12 then passes through the second heat exchanger 12a. Air entering the second heat exchanger 12a has water that has already been somewhat removed by the first heat exchanger 12, and the temperature of cooling water that is supplied to the second heat exchanger 12a has risen by passing through the first heat exchanger 12. Therefore, dew condensation does not occur in the second heat exchanger 12a.

Air that has passed through the second heat exchanger 12a enters inside the information processing apparatus main body 11. The air then cools the HDDs 24, the CPU 21 on which the heat sink 26 is mounted, the memory 22, and the like.

Air whose temperature has risen because of cooling of the HDDs 24, the CPU 21, the memory 22, and the like passes from the air discharge surface of the information processing apparatus main body 11 through the evaporator 13 and is discharged to the outside.

Air entering the evaporator 13 has a high temperature and a low humidity, and therefore when the air comes into contact with the evaporator 13, the water in the air evaporates from the capillaries 33 (refer to FIG. 3). As water evaporates, the evaporation heat is removed from the surroundings. Therefore, when air comes into contact with the evaporator 13, the temperature of the air decreases and the humidity rises.

The control system relevant to the pump 72 of the information processing apparatus 10a according to the second embodiment is basically similar to that in the first embodiment described above, and therefore description thereof is omitted here.

In the second embodiment, similar advantages to the first embodiment may be achieved. In addition, in the second embodiment, the temperature of air entering inside the information processing apparatus main body 11 may be further reduced owing to the second heat exchanger 12a compared with the case in the first embodiment. Accordingly, there are advantages in that electronic components such as the HDDs 24, the CPU 21, and the memory 22 may be more reliably cooled.

### Third Embodiment

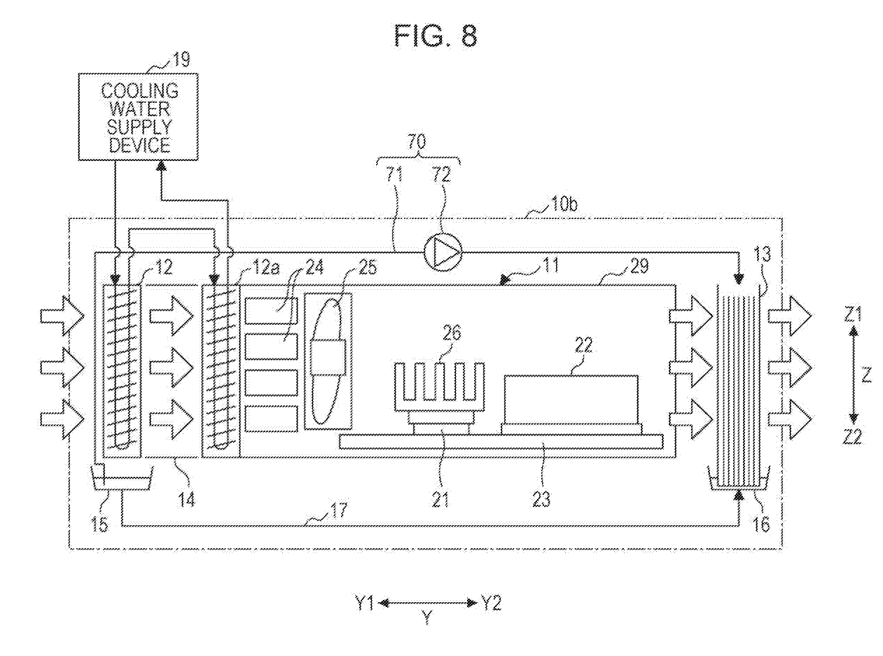

FIG. 8 is a schematic diagram illustrating an information processing apparatus according to a third embodiment. In FIG. 8, the same objects as in FIGS. 1-3 are denoted by the same reference numerals, and a detailed description thereof is omitted.

In an information processing apparatus 10b according to the third embodiment, the second heat exchanger 12a is disposed between the air intake surface of the information processing apparatus main body 11 and the HDDs 24. Cooling water supplied from the cooling water supply device 19 passes inside the first heat exchanger 12, then passes inside the second heat exchanger 12a, and returns to the cooling water supply device 19.

Operations of the information processing apparatus 10b according to the third embodiment are basically similar to those in the second embodiment, and description thereof is omitted here. The control system relevant to the pump 72 of the information processing apparatus 10b according to the third embodiment is basically similar to that in the first embodiment described above, and description thereof is omitted here.

In the third embodiment, the second heat exchanger 12a is disposed near the air blower 25. Therefore, a sufficient rate of flow of air may be ensured even when the density of fins of the second heat exchanger 12a is increased. Accordingly, the cooling capability of the second heat exchanger 12a may be improved, such that the HDDs 24, the CPU 21, the memory 22, and the like may be more reliably cooled.

### Fourth Embodiment

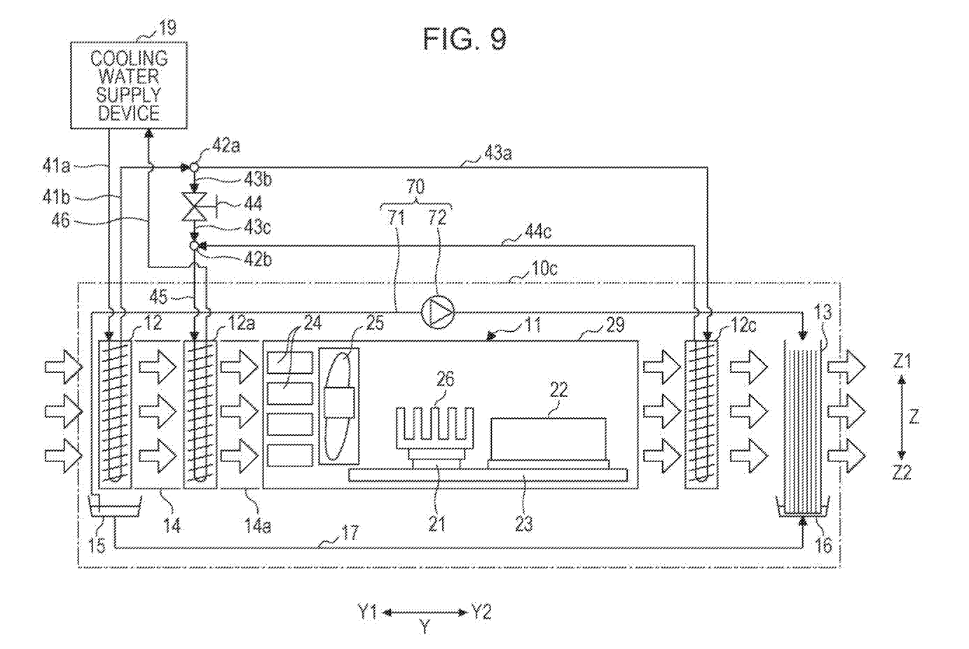

FIG. 9 is a schematic diagram illustrating an information processing apparatus according to a fourth embodiment. In FIG. 9, the same objects as in FIGS. 1-3 are denoted by the same reference numerals, and a detailed description thereof is omitted.

In an information processing apparatus 10c according to the fourth embodiment, the second heat exchanger 12a is disposed between the first heat exchanger 12 and the information processing apparatus main body 11. A third heat exchanger 12c is disposed between the air discharge surface of the information processing apparatus main body 11 and the evaporator 13. The structures of the second heat exchanger 12a and the third heat exchanger 12c are basically similar to the structure of the first heat exchanger 12 (refer to FIG. 2). A control system relevant to the pump 72 of the information processing apparatus 10c according to the fourth embodiment is basically similar to the control system in the first embodiment described above, and description thereof is omitted here.

The duct 14 is disposed between the first heat exchanger 12 and the second heat exchanger 12a, and the duct 14a is disposed between the second heat exchanger 12a and the air intake surface of the information processing apparatus main body 11.

As illustrated in FIG. 9, a cooling water supply port of the cooling water supply device 19 is connected via piping 41a to a cooling water inlet of the first heat exchanger 12. A cooling water outlet of the first heat exchanger 12 is connected via piping 41b to a cooling water inlet of a branching junction 42a.

A first cooling water outlet of the branching junction 42a is connected via piping 43b to a cooling water inlet of a valve 44, and a cooling water outlet of the valve 44 is connected via piping 43c to a first cooling water inlet of a merging junction 42b.

A second cooling water outlet of the branching junction 42a is connected via piping 43a to a cooling water inlet of the third heat exchanger 12c. A cooling water outlet of the third heat exchanger 12c is connected via piping 44c to a second cooling water inlet of the merging junction 42b.

A cooling water outlet of the merging junction 42b is connected via piping 45 to a cooling water inlet of the second heat exchanger 12a. A cooling water outlet of the second heat exchanger 12a is connected via piping 46 to a cooling water inlet of the cooling water supply device 19.

A piping path of cooling water is made up of these pieces of piping 41a, 41b, 43a, 43b, 43c, 44c, and 45, the branching junction 42a, and the merging junction 42b.

Also in the fourth embodiment, air introduced into the information processing apparatus main body 11 is cooled by the first heat exchanger 12 and the second heat exchanger 12a. After cooling the HDDs 24, the CPU 21, the memory 22, and the like in the information processing apparatus main body 11, air is discharged via the third heat exchanger 12c and the evaporator 13 to the outside of the information processing apparatus 10c.

Cooling water having a temperature of, for example, 10° C. to 15° C. is supplied from the cooling water supply device 19 to the first heat exchanger 12. Therefore, when the humidity of air introduced into the information processing apparatus 10c is high, dew condensation is generated inside the first heat exchanger 12 and water falls into the receiving pan 15. As in the first embodiment, the water that has fallen into the receiving pan 15 moves through the flow channel 17 to the water storage pan 16 and evaporates from the evaporator 13. As in the first embodiment described above, during operation of the pump 72, condensation water is supplied through the flow channel 71 to the top of the evaporator 13, and evaporates from the evaporator 13.

Cooling water from the first heat exchanger 12 branches off at the branching junction 42a, such that a portion of the cooling water moves inside the third heat exchanger 12c to the merging junction 42b and the remaining portion moves from the branching junction 42a through the valve 44 to the merging junction 42b. The cooling water that has moved through the valve 44 to the merging junction 42b and the cooling water that has moved inside the third heat exchanger 12c to the merging junction 42b are joined together, and the joined cooling water is supplied to the second heat exchanger 12a.

Accordingly, a temperature T3 of the cooling water supplied to the second heat exchanger 12a is a temperature between a temperature T1 of the cooling water exiting the first heat exchanger 12 and a temperature T2 of the cooling water exiting the third heat exchanger 12c (T1≤T3≤T2). The temperature T3 of the cooling water supplied to the second heat exchanger 12a may be adjusted by the extent to which the valve 44 is opened.

According to the second embodiment described above, cooling water exiting the first heat exchanger 12 is directly supplied to the second heat exchanger 12a. Therefore, there is a possibility that the temperature of air supplied to the information processing apparatus main body 11 might be lower than an appropriate range. In contrast, according to the fourth embodiment, some of the exhaust heat discharged from the information processing apparatus main body 11 is collected by the third heat exchanger 12c, so that the temperature of the cooling water supplied to the second heat exchanger 12a is adjusted. Thus, air at a temperature in the appropriate range may be supplied to the information processing apparatus main body 11.

### Fifth Embodiment

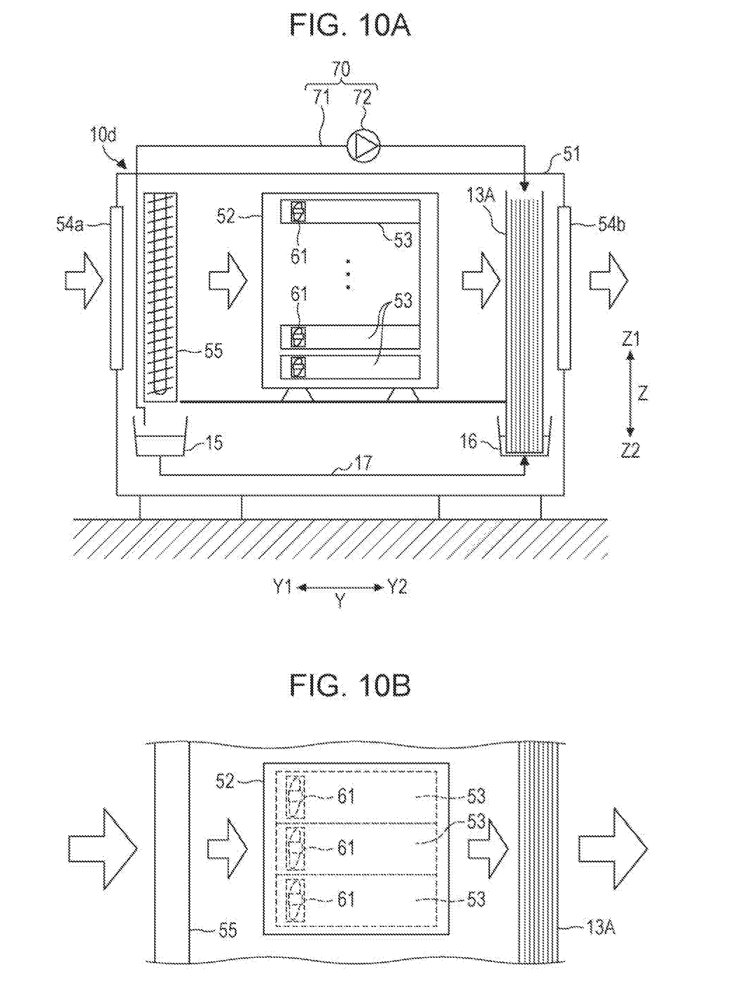

FIG. 10A is a schematic diagram illustrating a side view of an information processing apparatus according to a fifth embodiment. FIG. 10B is a schematic diagram illustrating a top view of the information processing apparatus according to the fifth embodiment. In the fifth embodiment, an example in which an information processing apparatus is applied to a container-type data center is demonstrated. In FIG. 10B, an information processing apparatus is only partially illustrated in the width direction, and the supply section 70 and so on are not illustrated. Although not illustrated in FIG. 10A and FIG. 10B, a cooling water supply device relevant to a heat exchanger 55 may be similar to the cooling water supply device 19 illustrated in FIG. 1.

As illustrated in FIG. 10A and FIG. 10B, a rack 52 are arranged inside a container 51 of an information processing apparatus 10d. In the rack 52, a plurality of servers 53 are arranged side by side in the height direction thereof and the width direction of the rack 52. In a modification, the plurality of servers 53 may be arranged side by side only in the height direction in the rack 52. The configuration of the server 53 may be similar to the configuration of the information processing apparatus main body 11 according to the first embodiment described above. Container 51 is not limited to enclosing only one rack 52 and may enclose a plurality of racks.

An air intake port 54a and the heat exchanger 55 are provided on one side of the container 51, and an air discharge port 54b and an evaporator 13A are provided on the other side. The receiving pan 15 is disposed below the heat exchanger 55, the water storage pan 16 is disposed below the evaporator 13A, and the receiving pan 15 and the water storage pan 16 communicate with each other by the flow channel 17.

The evaporator 13A has approximately the same height as the height of the rack 52. The evaporator 13A also has a width that is approximately the same as the width of the rack 52 (the length in the vertical direction of the drawing in FIG. 10A) or is greater than or equal to the width of the rack 52. For example, the evaporator 13A is provided in such a manner as to face the substantial entirety of the air discharge surface (back surface) of the rack 52. In FIG. 10A, the evaporator 13A extends vertically from below the rack 52 to the upper end of the rack 52. This enables transpiration of condensation water by making maximum use of air discharge. In a modification, a plurality of evaporators 13A may be provided separately in the width direction thereof for the rack 52.

The heat exchanger 55 is provided with a cool water pipe and fins (refer to FIG. 2) as in the first embodiment, and cooling water from a cooling water supply device (refer to FIG. 1) is supplied to the heat exchanger 55. The evaporator 13A is provided with capillaries (refer to FIG. 3), and water in the water storage pan 16 rises up in the capillaries by capillary action.

In each server 53 housed in the rack 52, an air blower 61 and a circuit board (not illustrated) on which electronic components such as a CPU are mounted are housed.

Hereinafter, operations of the information processing apparatus 10d according to the fifth embodiment will be described.

When the air blower 61 operates, air (outside air) is introduced from the air intake port 54a into the container 51 as indicated by arrows in FIG. 10A. For example, here, air having a temperature of 50° C. and a dew point of 40° C. (the humidity being about 60% RH) is introduced into the container 51.

The air introduced from the air intake port 54a into the container 51 is cooled when passing through the heat exchanger 55, such that dew condensation occurs inside the heat exchanger 55. Water generated by dew condensation falls into the receiving pan 15 and moves through the flow channel 17 to the water storage pan 16. As in the first embodiment described above, during operation of the pump 72, condensation water is supplied through the flow channel 71 to the top of the evaporator 13A and evaporates from the evaporator 13A.

For example, here, air that has passed through the heat exchanger 55 has a temperature of 25° C. and a dew point of 15° C. (the humidity being about 50% RH). The air that has been cooled by the heat exchanger 55 enters inside the rack 52 to cool electronic components in the servers 53.

The air whose temperature has risen by cooling the electronic components passes through the evaporator 13A and is discharged from the air discharge port 54b to the outside. When air comes into contact with the evaporator 13A, water in the evaporator 13A evaporates, such that the temperature of the air decreases and the humidity of the air rises.

In the first to fourth embodiments, one heat exchanger 12 and one evaporator 13 are disposed in each information processing apparatus. In contrast, in the fifth embodiment, one heat exchanger 55 and one evaporator 13A are disposed for a plurality of information processing apparatuses (the servers 53). Therefore, compared with the first to fourth embodiments, the numbers of receiving pans, water storage pans, and flow channels may be reduced.

A control system relevant to the pump 72 of the information processing apparatus 10d according to the fifth embodiment is basically similar to the control system in the first embodiment described above, and therefore description thereof is omitted here.

In the fifth embodiment, the evaporator 13A is provided on the upstream side (on the side close to the air intake port 54a) of the air discharge port 54b. However, the evaporator 13A may be provided on the downstream side of the air discharge port 54b.

In comparison with a comparative example, advantages of the fifth embodiment will be further described.

As a comparative example, a configuration that does not include the supply section 70 is assumed here. For example, in the comparative example, condensation water in the receiving pan 15 is supplied through the flow channel 17 to the bottom of the evaporator 13A.

The condensation-water evaporation mechanism of the evaporator 13A makes use of capillary action and therefore there is a limit to how high condensation water may be raised. For example, a rack for the information processing apparatus main body 11 of 40 U to 42 U (1 U=44.45 mm (1.75 inches)) has a height of about 2000 mm. However, capillaries are incapable of supplying condensation water to this height. In the case where the amount of condensation water is large, the condensation-water suction capability by capillary forces obstructs transpiration of the condensation water. Thus, transpiration of condensation water may not be effectively achieved. For example, in the case of an information processing apparatus that requires a high airflow, condensation water increases in proportion to the airflow volume. However, because the condensation-water suction capability by capillary forces is fixed, there is a limit to suction of condensation water and transpiration thereof. This obstructs complete suction and transpiration of the condensation water. As a result, all of the condensation water is not converted back to discharged air.

In this regard, in the fifth embodiment, even when the evaporator 13A having a height corresponding to the height of the rack 52 is provided, by making use of the pump 72 with a pumping head higher than the height of the evaporator 13A, condensation water may be reliably supplied (transported) via the flow channel 71 to the top of the evaporator 13A. The amount of condensation water capable of being supplied (transported) via the flow channel 71 to the top of the evaporator 13A may be easily adjusted, for example, by controlling the pump 72. Accordingly, in the fifth embodiment, the condensation-water transportation capability with the pump 72 does not obstruct evaporation of condensation water. Thus, transpiration of condensation water may be effectively achieved. For example, when condensation water increases in proportion to an air flow volume, condensation water may be supplied via the flow channel 71 to the top of the evaporator 13A in such a manner as to compensate for the condensation-water suction capability by capillary forces. As a result, even when condensation water increases in proportion to an air flow volume, all of the condensation water may be converted back to discharged air.

Accordingly, the information processing apparatus 10d according to the fifth embodiment may also be installed as a container-type data center in a hot and humid region. The construction period is short, which is advantageous in that electric power required for cooling an information processing apparatus may be drastically reduced.

In the fifth embodiment, only the heat exchanger 55 is provided. However, as in the second embodiment described above, the second heat exchanger 12a and the duct 14a may also be provided, and, as in the third embodiment described above, the second heat exchanger 12a may also be provided. As in the fourth embodiment described above, the third heat exchanger 12c may also be provided.

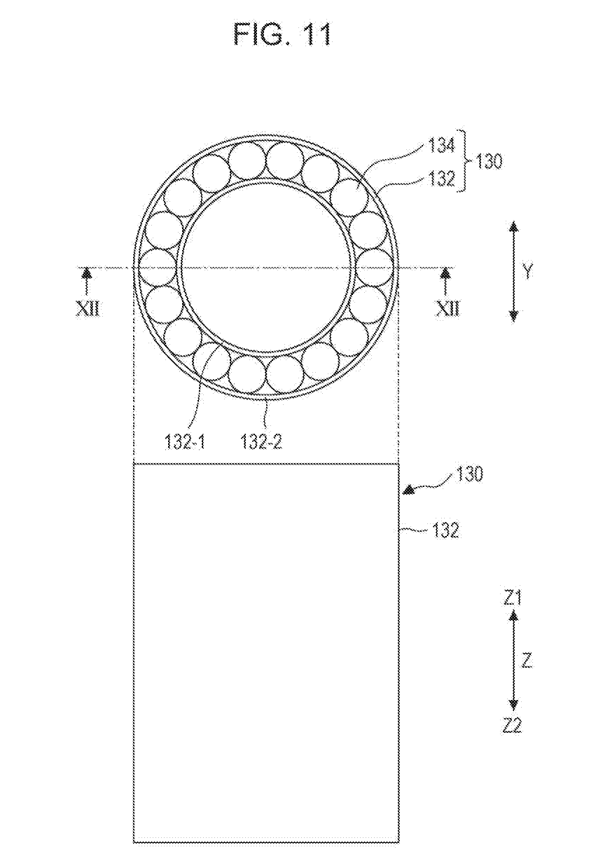

Referring now to FIG. 11 and the subsequent drawings, an example of a desirable configuration of a preferable evaporator as the evaporator 13 (similarly for the evaporator 13A) will be described.

FIG. 11 is a two-view drawing illustrating the evaporator 130 by way of example, and the upper drawing is a plan view and the lower drawing is a side view.

The evaporator 130 includes a cylindrical porous medium 132 and a member 134 with which capillary action occurs (hereinafter referred to as a capillary member 134).

The porous medium 132 has a cylindrical shape whose axial direction coincides with the vertical direction thereof. The porous medium 132 forms the main body of the evaporator 130, and the height of the porous medium 132 determines the height of the evaporator 130. The porous medium 132 may be formed, for example, of fiber or a sintered block.

In the example illustrated in FIG. 11, the porous medium 132 includes a first porous portion 132-1 and a second porous portion 132-2 apart from each other in the radial direction. For example, the porous medium 132 has such a configuration that the first porous portion 132-1 and the second porous portion 132-2, which are cylindrical with different diameters, are concentrically arranged. The first porous portion 132-1 and the second porous portion 132-2 may have similar configurations except for different diameters.

The capillary member 134 is provided in such a manner as to be in contact with the porous medium 132 and, for example, is disposed near the surface on the outside in the radial direction of the porous medium 132. This allows air to be more likely to come into contact with the capillary member 134, efficiently achieving transpiration of condensation water. The capillary member 134 extends vertically over the full height of the porous medium 132. This allows transpiration of condensation water to be achieved by making maximum use of space in the height direction. However, in a modification, the capillary member 134 may extend over part of the height of the porous medium 132.

The capillary member 134 may be formed, for example, of a bundle of fiber (for example, polyester fiber), a bundle of capillaries (for example, tubes with internal diameters less than 1 mm), a bar member with a porous medium, or the like.

The capillary member 134 further extends in the circumferential direction of the porous medium 132. In the example illustrated in FIG. 11, a plurality of capillary members 134 are arranged along the circumferential direction of the porous medium 132. This allows transpiration of condensation water to be achieved by making maximum use of the circumferential range where air is able to pass in the porous medium 132. For example, the capillary members 134 having cylindrical shapes are arranged between the first porous portion 132-1 and the second porous portion 132-2 in the radial direction. However, in a modification, the capillary member 134 may be plate-shaped and be rolled up on the circumference of a circle to extend in the circumferential direction of the porous medium 132. For example, in the modification, the capillary member 134 may have a cylindrical shape extending between the first porous portion 132-1 and the second porous portion 132-2 in the radial direction and in the circumferential direction of the porous medium 132. In another modification, the capillary member 134 may have such an indefinite shape that the capillary member 134 is packaged between the first porous portion 132-1 and the second porous portion 132-2 in the radial direction.

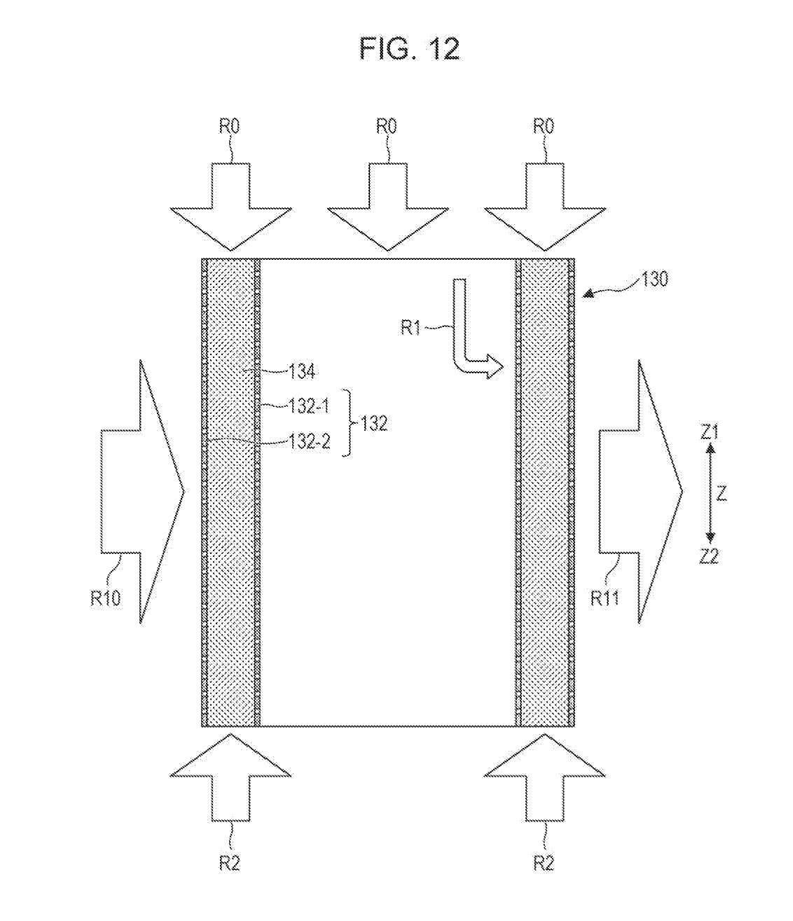

FIG. 12 is an illustrative diagram of the functions of the evaporator 130 and is a sectional view taken along the line XII-XII in FIG. 11. The arrows R10 and R11 in FIG. 12 indicate the direction of air flow. The direction indicated by the arrows R10 and R11 corresponds to the direction of air flow from the upstream side to the downstream side. The arrows R0 and R1 in FIG. 12 schematically indicate the direction of flow of condensation water supplied via the flow channel 71 by the pump 72, and the arrows R2 schematically indicate the direction of flow (the direction of capillary action) of condensation water in the water storage pan 16.

In the example illustrated in FIG. 12, as schematically indicated by the arrows R0, condensation water supplied via the flow channel 71 by the pump 72 moves downward by gravity from the entire top of the evaporator 130. At this point, as schematically indicated by the arrow R1, part of condensation water flows downward along the inner circumferential surface of the porous medium 132 (precisely, the inner circumferential surface of the second porous portion 132-2). This allows condensation water to be supplied to the vicinity of an intermediate position (an intermediate position in the height direction) of the evaporator 130, and thus, in the vicinity of the intermediate position, the condensation water is able to be introduced through pores of the first porous portion 132-1 into the capillary members 134 on the outside in the radial direction. As a result, the distribution of the evaporation amount of condensation water may be made uniform in the height direction of the capillary members 134. This may lead to more efficiency in transpiration of condensation water in the capillary members 134. The transpiration of condensation water in the capillary members 134 is achieved via air passing through pores of the porous medium 132. Part of the condensation water is transpired inside of pores or on the surface of the porous medium 132, and therefore the velocity of transpiration (for example, the evaporation amount per unit time) of condensation water may be more efficiently increased than when only the capillary members 134 are used.

The porous medium 132 of the evaporator 130 has a two-layered structure of the first porous portion 132-1 and the second porous portion 132-2. However, the porous medium 132 may have a three-or-more-layered structure such as a three-layered structure.

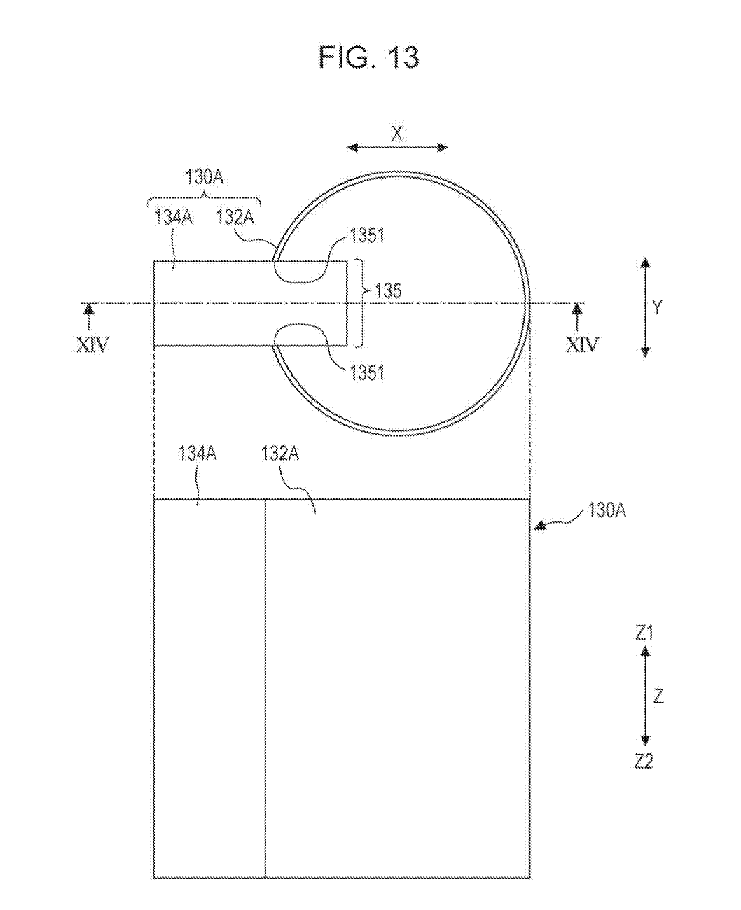

FIG. 13 is a two-view drawing illustrating an evaporator 130A by way of another example, and the upper drawing is a plan view and the lower drawing is a side view. In FIG. 13, the X-direction and the Y-direction orthogonal to the Z-direction are illustrated.

The evaporator 130A includes a cylindrical porous medium 132A and a capillary member 134A. The evaporator 130A may be disposed in such an orientation that the Y-direction matches the direction of flow of air from the upstream side to the downstream side.

The porous medium 132A has a cylindrical shape whose axial direction coincides with the vertical direction thereof. The porous medium 132A forms the main body of the evaporator 130A, and the height of the porous medium 132A determines the height of the evaporator 130A. The porous medium 132A may be formed, for example, of fiber or a sintered block.

In the example illustrated in FIG. 13, the porous medium 132A includes a cut-out portion 135 in a part in the circumferential direction thereof. The cut-out portion 135 extends vertically over the full height of the porous medium 132A. However, in a modification, the cut-out portion 135 may extend over part of the height of the porous medium 132A.

The capillary member 134A extends vertically over the full height of the porous medium 132A. However, in a modification, the capillary member 134A may extend over part of the height of the porous medium 132A. The capillary member 134A may be formed, for example, of a bundle of fiber, a bundle of capillaries (for example, tubes with internal diameters less than 1 mm), a bar member with a porous medium, or the like.

In the example illustrated in FIG. 13, the capillary member 134A is provided in the cut-out portion 135 of the porous medium 132A. For example, the capillary member 134A has a rectangular parallelepiped shape and extends through the cut-out portion 135 in the radius direction of the porous medium 132A. On this occasion, the capillary member 134A is in contact with (in radial abutment with) edges 1351 of the cut-out portion 135. However, in a modification, the capillary member 134A may have a shape other than the rectangular parallelepiped shape. In another modification, the capillary member 134A may be provided at each of a plurality of positions along the circumferential direction of the porous medium 132A.

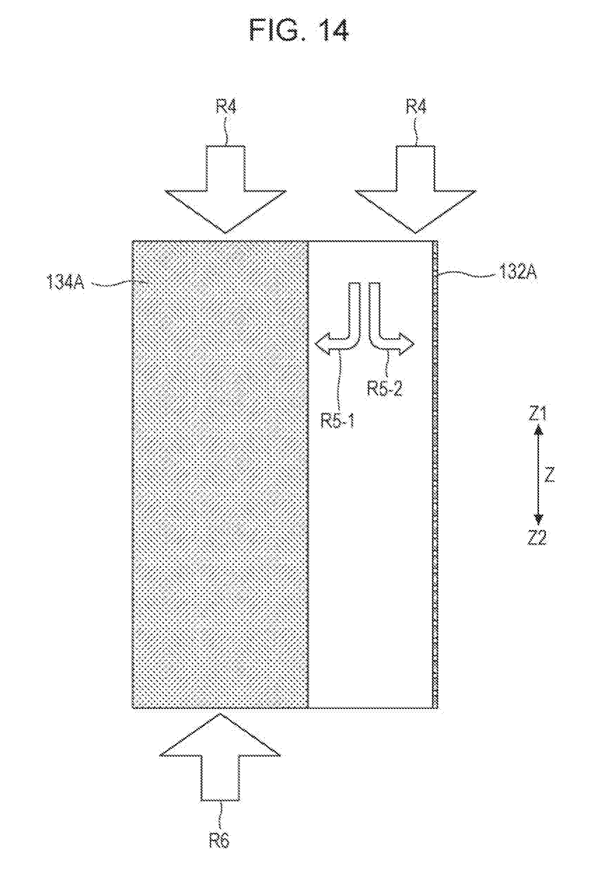

FIG. 14 is an illustrative diagram of the functions of the evaporator 130A and is a sectional view taken along the line XIV-XIV in FIG. 13. The arrows R4, R5-1, and R5-2 in FIG. 14 schematically indicate the flow direction of condensation water supplied via the flow channel 71 by the pump 72, and the arrow R6 schematically indicates the flow direction (the direction of capillary action) of condensation water in the water storage pan 16.

In the example illustrated in FIG. 14, as schematically indicated by the arrows R4, condensation water supplied via the flow channel 71 by the pump 72 moves downward by gravity from the entire top of the evaporator 130A. At this occasion, as schematically indicated by the arrow R5-1, part of condensation water flows downward along the internal circumferential surface of the porous medium 132A. This allows condensation water to be supplied to the vicinity of an intermediate position (an intermediate position in the height direction) of the evaporator 130A, and thus, in the vicinity of the intermediate position, the condensation water is able to be introduced into the capillary member 134A on the outside in the radial direction. As a result, the distribution of the evaporation amount of condensation water may be made uniform in the height direction of the capillary member 134A. This may lead to more efficiency in transpiration of condensation water in the capillary member 134A. As schematically indicated by the arrow R5-2, part of the condensation water flows downward along the internal circumferential surface of the porous medium 132A and, at that occasion, comes into contact with air. Accordingly, part of the condensation water is transpired inside of pores or on the surface of the porous medium 132A, and therefore the velocity of transpiration (for example, the evaporation amount per unit time) of the condensation water may be more efficiently increased than when only the capillary members 134 are used.

As described above, the embodiments have been described in detail. However, the embodiments disclosed herein are not limited to specific embodiments and various modifications and changes may be made without departing from the scope of the claims. All or a plurality of elements of the embodiments described above may be combined.

For example, in the first embodiment described above (similarly in the second to fifth embodiments), the pump 72 draws up condensation water in the receiving pan 15. However, the way to draw up condensation water is not limited to this. For example, the pump 72 may draw up condensation water in the water storage pan 16 to supply the drawn condensation water to the top of the evaporator 13. In such a case, the flow channel 71 may extend from the water storage pan 16 to the top of the evaporator 13.

In the first embodiment described above (similarly in the second to fifth embodiments), the flow channel 17 as well as the supply section 70 is provided. However, the flow channel 17 may be removed. That is, a configuration in which condensation water in the receiving pan 15 is supplied via the flow channel 71 only to the top of the evaporator 13. In such a case, supplying condensation water via the flow channel 71 to the top of the evaporator 13 enables the condensation water to be efficiently evaporated with the evaporator 13 by making use of the gravity of the condensation water without drawing up the condensation water by capillary forces.

In the first embodiment described above (similarly in the second to fifth embodiments), air is sucked and discharged in such a manner as to flow in the Y-direction. However, the manner in which air is sucked and discharged is not limited to this. For example, air may be vertically sucked and discharged. In such a case, the information processing apparatus 10 is disposed to be in such an orientation that the vertical direction thereof coincides with the Y-direction, and thus the discharge side thereof is the upper side. In such a case, the receiving pan 15 may be disposed below the heat exchanger 12, and condensation water may be supplied to the top of the evaporator 13 by the supply section 70.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A device for cooling electronic components comprising:
a main body including the electronic components;
an air blower configured to introduce air into the main body;
a heat exchanger configured to cool air introduced into the main body;
an evaporator with which air discharged from the main body comes into contact; and
a pump configured to draw up water generated by dew condensation in the heat exchanger and to supply the water to a top portion of the evaporator.

2. The device for cooling electronic components according to claim 1, wherein the evaporator includes a cylindrical porous medium whose axial direction coincides with a vertical direction, and a member to cause capillary action extending in the vertical direction in such a manner as to be in contact with the porous medium.

3. The device for cooling electronic components according to claim 2, wherein the member further extends in a circumferential direction of the porous medium in such a manner as to be in contact with the porous medium.

4. The device for cooling electronic components according to claim 2, wherein
the porous medium includes a first porous portion and a second porous portion that are apart in a radial direction of the porous medium, and
the member is disposed between the first porous portion and the second porous portion in the radial direction.

5. The device for cooling electronic components according to claim 2, wherein
the porous medium includes a cut-out portion in a part in a circumferential direction of the porous medium, and
the member extends in a radial direction of the porous medium through the cut-out portion in such a manner as to be in contact with an edge of the cut-out portion in the porous medium.

6. The device for cooling electronic components according to claim 2, wherein the member includes fiber.

7. The device for cooling electronic components according to claim 1, wherein the evaporator extends vertically over a full height of the main body.

8. The device for cooling electronic components according to claim 1, further comprising:
a plurality of main bodies, and
a rack capable of mounting the plurality of main bodies such that the plurality of main bodies are vertically disposed side by side,
wherein the evaporator extends vertically over a full height of the rack.

9. The device for cooling electronic components according to claim 1, further comprising a receiving pan disposed below the heat exchanger, and a first flow channel extending between the receiving pan and the evaporator,
wherein the pump is disposed in the first flow channel.

10. The device for cooling electronic components according to claim 9, further comprising
a second flow channel configured to supply water of the receiving pan to a bottom portion of the evaporator.

11. The device for cooling electronic components according to claim 1, further comprising a controller configured to control the pump in accordance with an amount of the water.

12. The device for cooling electronic components according to claim 11, wherein the controller is configured to increase a water amount drawn up by the pump when the amount of the water is greater than a predetermined amount.

13. The device for cooling electronic components according to claim 1, wherein
the heat exchanger includes a conduit through which a refrigerant passes and a fin disposed on the conduit, and
the water includes water generated by dew condensation on a surface of the fin.

14. The device for cooling electronic components according to claim 13, wherein the refrigerant includes cooling water at an environmental temperature or less supplied from a cooling water supply device.

15. The device for cooling electronic components according to claim 1, wherein the air blower is disposed to cause air to flow in a direction toward the evaporator in the main body.

16. A device for cooling electronic components comprising:
an enclosure housing one or more electronic components;
a fan, positioned outside of a first end of the enclosure, configured to create an air flow through the enclosure;
a heat exchanger configured to cool air introduced to the enclosure;
an evaporator, positioned outside of a second end of the enclosure opposite the first end, through which the air flow passes; and
a water supply device including a pump and configured to supply water generated by condensation from the heat exchanger to the evaporator.

17. The device of claim 16, further comprising a receiving pan positioned below the heat exchanger to collect condensation generated by the heat exchanger.

18. The device of claim 17, wherein the pump supplies condensation in the receiving pan to a top portion of the evaporator through a first flow channel.

19. The device of claim 18, wherein the storage pan and the receiving pan are connected by a second flow channel.
